(19) United States
(12) Patent Application Publication
(10) Pub. No.: US 2026/0181839 A1
(43) Pub. Date: Jun. 25, 2026

(54) DYNAMIC PRESSURE-BASED CONTROL SYSTEM OF A DATACENTER FLUID COOLING ARRANGEMENT

(71) Applicant: OVH, Roubaix (FR)

(72) Inventors: Ali CHEHADE, Moncheaux (FR); Mohamad HNAYNO, La Madeleine (FR)

(21) Appl. No.: 19/412,023

(22) Filed: Dec. 8, 2025

(30) Foreign Application Priority Data
Dec. 20, 2024 (EP) 24307252.7

(51) Int. Cl. H05K 7/20

(52) U.S. Cl. CPC H05K 7/20836; H05K 7/20781

(57) ABSTRACT

The disclosed embodiments are provide a liquid cooling arrangement and method for a server rack including input and output temperature sensors of the server rack, a liquid cooling subsystem comprising a pump unit to forcibly urge the cooling liquid flow, a liquid distribution circuit fluidly-coupled to the liquid cooling subsystem and the server rack and configured to convey the cooling liquid to/from the server rack, input and output pressure sensors configured to measure the pressure of the cooling liquid flow received, and issued, by the pump unit, and a control unit. The control unit is configured to direct the pump unit to operate at full capacity, quantify pressure differences between the input/output pressure sensor measurements, determine an optimal volume flow rate based on a desired predetermined temperature difference between the input/output temperatures and empirical pump operational characteristics, and adjust the pump unit speed based on the determined optimal flow rate.

### CROSS-REFERENCE

The present patent application claims priority to European Patent Application Number 24307252.7 filed on Dec. 20, 2024, the disclosure of which is hereby incorporated by reference herein in its entirety.

### FIELD

The present technology generally relates to the field of datacenter cooling measures and, in particular, to the pressure control of datacenter liquid cooling arrangements.

### BACKGROUND

Datacenters as well as many computer processing facilities house multitudes rack-mounted electronic processing equipment. In operation, such electronic processing equipment generates a substantial amount of heat that must be dissipated to avoid electronic component failures and ensure continued processing performance. It should also appreciated that the level of heat generated by the electronic processing equipment is correlated to processing demands that may fluctuate on an hourly, daily, or weekly basis.

To this end, various liquid cooling measures have been implemented to facilitate the dissipation of heat generated by the electronic processing equipment. One such measure employs liquid block cooling techniques for directly cooling one or more heat-generating processing components. This technique utilizes liquid cooling blocks having internal channels that receive cooling liquid from a cooling liquid source, e.g., heat exchangers, dry coolers, etc., via a liquid cooling circuit arrangement to circulate the cooling liquid throughout the equipment. As such, the liquid cooling blocks are positioned to be in direct thermal contact with the heat-generating components, so that the received cooling liquid absorbs the generated heat and the heated liquid is circulated, via the cooling circuit arrangement, back to cooling liquid source for re-cooling.

As noted above, the demand for processing resources fluctuates. As such, there remains an interest in improving the control of liquid cooling components and resources that take into account fluctuating demand to optimize operating efficiencies.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches.

### SUMMARY

Embodiments of the present technology have been developed based on the interest to improve the efficiency of conventional liquid cooling techniques and implementations. To this end, developers have addressed this issue by providing a solution that intelligently controls pump operations to dynamically adjust the cooling liquid pressure and flow rate based on certain events or periodically-assessed demand levels.

Therefore, one embodiment of the present technology is directed to a liquid cooling arrangement for providing a cooling liquid to datacenter rack-mounted server data processing assemblies, that contains a server branch comprising a server rack for housing the rack-mounted server processing assemblies and a smart control valve configured to control a flow of the cooling liquid supplied to the server rack; a liquid cooling subsystem comprising a pump unit configured to forcibly urge a flow of the cooling liquid from the liquid cooling subsystem to and from the server rack and an output pressure sensor configured to measure the pressure of the cooling liquid flow Po forcibly urged by the pump unit, the pump unit configured with a constant pressure operational mode setting that controls a speed of the pump unit to provide a cooling liquid pressure at a set constant pressure level; a liquid distribution circuit fluidly-coupled to the liquid cooling subsystem, the smart control valve, and the server rack, the liquid distribution circuit configured to convey the cooling liquid from the liquid cooling subsystem to the server rack and convey the heated liquid from the server rack back to the liquid cooling subsystem for recooling and recirculation therethrough; a feedback control system comprising a control unit and receiving a heat load level Q of the server rack for determining the constant pressure operational mode setting of the pump unit. The control unit is configured with executable instructions to: direct the pump unit to operate at full speed to provide a maximum pressure of cooling liquid flow; direct the smart control valve to open at maximum flow rate capacity; determine an optimal volume flow rate mₒₚₜ based on the heat load level Q of the server rack and an empirical operational characteristic based on pump speeds and corresponding volume flow rates; determine a lowest efficient pump speed PS_{L} that maintains the optimal cooling liquid flow rate mₒₚₜ; and set the constant pressure operational mode setting of the pump unit to operate in accordance with the determined lowest efficient pump speed PS_{L}. The the empirical pump operational characteristics define an efficient system operations curve relative to volume flow rates, pump speeds, and pump power consumption levels.

In a related aspect of the liquid cooling arrangement, the control unit is further configured to communicate with, and receive from, the pump unit and the smart control valve input and output cooling liquid temperatures levels Ti, To of the server rack (150-15L) to quantify the cooling liquid temperature difference ΔT and pump unit input and output pressure levels Pi, Po to quantify a pump pressure difference ΔP receive a cooling liquid temperature difference ΔT between input and output server rack cooling liquid temperatures, wherein the optimal volume flow rate mₒₚₜ is further based on ΔT and ΔP.

Another embodiment of the present technology is directed to a liquid cooling method for providing a cooling liquid to datacenter server data processing assemblies of a server rack that includes communicating with an input server rack temperature sensor, output server rack temperature sensor, input pump unit pressure sensor, output pump unit pressure sensor, and a smart control valve; directing the pump unit to operate at full capacity; directing the smart control valve to open at maximum flow rate capacity; quantifying a pressure difference ΔP between the input pressure sensor measurement and the output pressure sensor measurement; determining an optimal volume flow rate mₒₚₜ based on a desired predetermined temperature difference ΔTd of X° K representing a desired temperature difference value between overall input and output temperatures and empirical pump operational characteristics regarding pump speeds and corresponding volume flow rates; determining a lowest efficient pump speed PS_{L} that maintains the optimal cooling liquid flow rate mₒₚₜ; and setting the constant pressure operational mode setting of the pump unit to operate in accordance with the determined lowest efficient pump speed PS_{L}.

In a related aspect of the liquid cooling method, including a control unit communicating with the pump unit and issuing the steps for determining of the optimal volume flow rate mₒₚₜ, the lowest efficient pump speed PS_{L}, and setting the constant pressure operational mode setting of the pump unit. Additionally, the determining of the optimal volume flow rate mₒₚₜ and the lowest efficient pump speed PS_{L} is performed over one or more iterations and initiated based on detected cooling liquid flow rate changes or detected increased server rack temperatures.

The invention also relates to a computer program and computer-readable medium comprising instructions which, when the program is executed by a computer, cause the computer to carry out the steps of the method as previously described.

In the context of the present specification, unless expressly provided otherwise, a computer system may refer, but is not limited to, an “electronic device”, an “operation system”, a “system”, a “computer-based system”, a “controller unit”, a “monitoring device”, a “control device” and/or any combination thereof appropriate to the relevant task at hand.

In the context of the present specification, unless expressly provided otherwise, the expression “computer-readable medium” and “memory” are intended to include media of any nature and kind whatsoever, non-limiting examples of which include RAM, ROM, disks (CD-ROMs, DVDs, floppy disks, hard disk drives, etc.), USB keys, flash memory cards, solid state-drives, and tape drives. Still in the context of the present specification, “a” computer-readable medium and “the” computer-readable medium should not be construed as being the same computer-readable medium. To the contrary, and whenever appropriate, “a” computer-readable medium and “the” computer-readable medium may also be construed as a first computer-readable medium and a second computer-readable medium.

Moreover, unless expressly provided otherwise, the words “first”, “second”, “third”, etc. have been used as adjectives only for the purpose of allowing for distinction between the nouns that they modify from one another, and not for the purpose of describing any particular relationship between those nouns. It should also be understood that terms relating to the position and/or orientation of components such as “upper”, “lower”, “top”, “bottom”, “front”, “rear”, “left”, “right”, are used herein to simplify the description and are not intended to be limitative of the particular position/orientation of the components in use.

Furthermore, the use of the phrase “at least one of A and B” is intended to mean A only, B only, or both A and B.

Implementations of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1A depicts a functional block diagram of a server cluster configuration of a datacenter server rack, in accordance with the non-limiting embodiments of the present disclosure;

FIG. 1B depicts a functional block diagram of a liquid cooling arrangement for servicing datacenter server racks, in accordance with the non-limiting embodiments of the present disclosure;

FIG. 2 depicts a functional block diagram of a liquid cooling arrangement for datacenter server racks directed to the control of a pump unit, in accordance with the non-limiting embodiments of the present disclosure;

FIG. 3 provides an exemplary graph depicting the functional relationship between pump unit pressure, cooling liquid flow rates, and pump power for efficient operations for the liquid cooling arrangement, in accordance with the non-limiting embodiments of the present disclosure;

FIG. 4 depicts a flow diagram of a process for periodically adjusting the control of the pump unit operations of the liquid cooling arrangement based on detected demand needs, in accordance with the nonlimiting embodiments of the present technology; and

FIG. 5 depicts a functional block diagram of a monitoring controller configured to execute processing control operations of the pump unit, in accordance with the nonlimiting embodiments of the present technology.

It is to be understood that, unless otherwise explicitly specified herein, the drawings are not necessarily rendered to scale. Moreover, the drawings may omit features or may exaggerate features in order to assist in the clear understanding of the disclosed embodiments.

### DETAILED DESCRIPTION

The instant disclosure is directed to addressing at least some of the issues associated with the conventional use of various piping conduit configurations and numerous pumps to supply the liquid flows to the liquid cooling blocks and to the air-to-liquid heat exchangers servicing the cooling needs of the multitude of heat-generating components.

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any diagrams presented herein represent conceptual views of illustrative systems embodying the principles of the present technology.

As noted above, the heat levels generated by the electronic processing equipment is correlated to processing demands that tend to fluctuate on an hourly, daily, or even weekly basis. It will be appreciated that consistently operating a pump unit at the same speed and flow rate consumes a constant amount of energy even when the demand is low. This contributes to inefficient energy consumption, excessive wear and tear on the pump unit, and inadequate system response times to fluctuating demand.

With these fundamentals in place, the following disclosures are directed to providing the intelligent control of pump operations to dynamically adjust the cooling liquid pressure and flow rate based on certain events or periodically-assessed fluctuating demand levels in order to optimize overall system efficiency, in accordance with the inventive aspects and principles of the present disclosure.

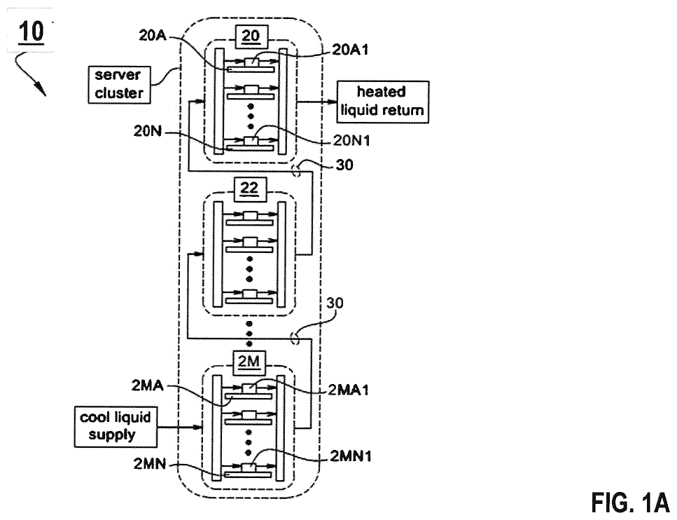

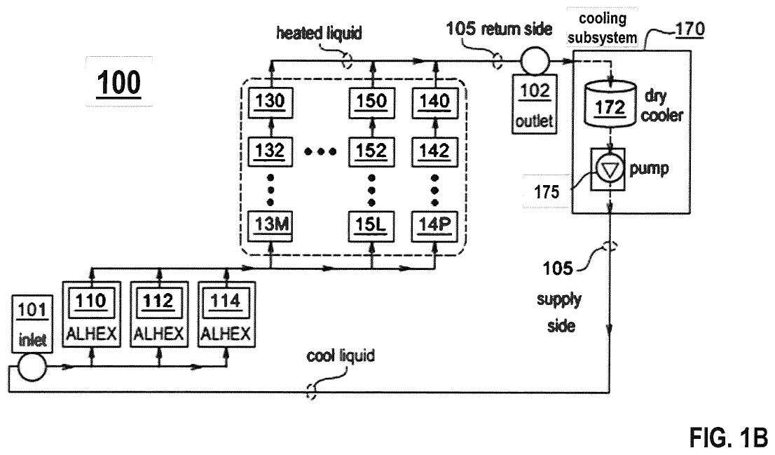

Accordingly, FIG. 1A depicts a functional block diagram of a representative internal server cluster 10 configuration of a datacenter server rack, in accordance with the non-limiting embodiments of the present disclosure. The representative server cluster 10 configuration comprises a plurality of server sub-clusters 20-2M, in which each server sub-cluster 20-2M correspondingly comprises a plurality of data processing assemblies 20A-20N to 2MA-2MN containing heat-generating electronic processing components. The heat-generating electronic components may comprise central processing units (CPUs), graphic processing units (GPUs), microcontroller units (MCUs), etc.

As shown, each of the data processing assemblies 20A-20N to 2MA-2MN incorporates at least one respective liquid cooling block unit (i.e., water blocks) 20A1-20N1 to 2MA1-2MN1 disposed in direct thermal contact with the heat-generating electronic processing components. Each of the water blocks 20A1-20N1 to 2MA1-2MN1 is configured with internal conduits (not shown) to accommodate the circulated flow of channelized cooling liquid therethrough. The channelized cooling liquid is provided by a cooling liquid supply that is serially conveyed to each of the water blocks 20A1-20N1 to 2MA1-2MN1 via an internal server cluster liquid circulating channel 30 to absorb the thermal energy from the heat-generating electronic components and discharge the heated liquid therefrom.

Given the internal datacenter server cluster 10 configuration described above, FIG. 1B depicts a functional block diagram of fluid cooling arrangement 100 for servicing the datacenter server racks, in accordance with the non-limiting embodiments of the present disclosure.

As shown, fluid cooling arrangement 100 comprises a single liquid distribution circuit 105 configured with a supply side for supplying a cooling liquid to the server clusters 130-13M, 140-14P, 150-15L of a rack from a liquid cooling subsystem 170 and a return side for returning a heated liquid from the servers back to the liquid cooling subsystem 170 for recooling and recirculation back to the servers clusters 130-15L. As noted above relative to FIG. 1A, each of the server clusters 130-15L comprise data processing assemblies (see, e.g., FIG. 1 20A-20N to 2MA-2MN) that incorporate at least one corresponding water block 20A1-20N1 for direct thermal contact with the heat-generating electronic components for dissipation of heat therefrom.

Accordingly, FIG. 1B indicates that liquid distribution circuit 105 is configured with a liquid distribution inlet 101 along the “cool” supply side for supplying the cooling liquid to the fluidly-coupled server clusters 130-15L and a liquid distribution outlet 102 along the “heated” return side for receiving a heated liquid from the server clusters 130-15L and returning the heated liquid back to the liquid cooling subsystem 170 for recooling and recirculation back to the server clusters 130-15L. The liquid distribution circuit 105 may be constructed from flexible materials (e.g., rubber, plastic, etc.), rigid materials (e.g., metal, PVC piping, etc.), or any combination of thereof. It will be appreciated that the conveyed cooling liquid may include water, alcohol, or any suitable liquid capable of sustaining adequate cooling temperatures. However, for the sake of consistency and understanding, the following disclosures will refer to the use of water as the cooling liquid or fluid.

As shown, the liquid cooling subsystem 170 comprises a dry cooler unit 172 configured to process and recondition the received heated water from the server racks to provide recooled water for recirculation back to the water blocks servicing the server clusters 130-15L via the liquid distribution circuit 105. The liquid cooling subsystem 170 further comprises a pump unit 175 configured to provide the necessary pressure and volume flow rate of the cooling water from the dry cooler unit 172 throughout the liquid distribution circuit 105. The operational control of pump unit 175 will be described in further detail below.

The fluid cooling arrangement 100 further includes a plurality of air-to-liquid heat exchangers (ALHEXs) 110-114. In the illustrated embodiment, the ALHEXs 110-114 are fluidly connected in parallel via the liquid cooling circuit 105 while also being fluidly coupled to the server clusters 130-15L via the liquid cooling circuit 105. It will be appreciated, however, that the ALHEXs 110-114 may be fluidly interconnected in other configurations, such as, for example, in series via the liquid cooling circuit 105 without departing from the concepts of the disclosed technology.

The ALHEXs 110-114 function to sufficiently cool the ambient air surrounding the server clusters 130-15L. The ALHEXs 110-114 may embody any suitable configuration that reduces temperatures of supplied air flow (e.g. by compact fans), such as, internal cooling coils, heat extracting air flow fins, etc. The ALHEXs 110-114 may be, for example, disposed on rear doors of the rack hosting the server clusters 130-15L, to directly cool the air exiting the server clusters 130-15L, warmed by the air-cooled components therein.

The status of the cooling water temperature within the distribution circuit 105 during use is described as follows: water flow egresses out of the liquid cooling subsystem 170 and enters the distribution circuit 105 at a “cooling” temperature that is supplied to the water blocks 20A1-20N1 that thermally coupled to the heat-generating electronic components. The cooling water flow is internally-circulated through each of the data processing assemblies of the server clusters 130-15L and standard priority server clusters 130-15L for liquid cooling. As a result, the internally-circulated water becomes heated due to the heat-generating electronic components.

The “heated” water is then is supplied to the return side of the liquid distribution circuit 105 to be returned back to the liquid cooling subsystem 170 for recooling and recirculation back to all the server clusters 130-15L. In certain implementations, the heated liquid temperature may range from approximately 45° C. to 65° C., while the “cold” temperature is chosen approximately between 20° C. to 40° C.

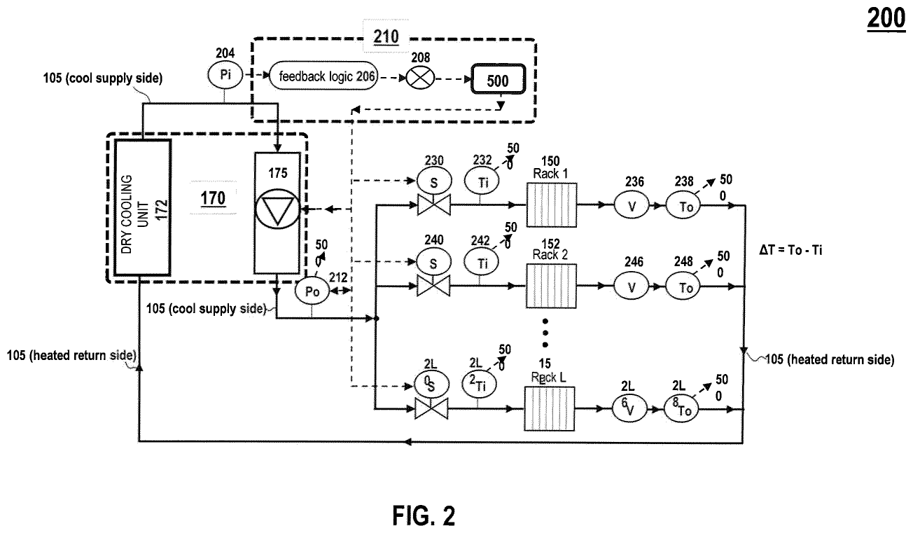

FIG. 2 depicts a functional block diagram of a liquid cooling arrangement 200 for datacenter server racks focusing on the dynamic control of pump unit 175 of the liquid cooling subsystem 170, in accordance with the non-limiting embodiments of the present disclosure. In particular, FIG. 2 provides a comprehensive view of the liquid cooling arrangement 200 configuration and components designed to provide the intelligent control of pump unit 175 operations for dynamically adjusting the cooling liquid pressure and flow rate based on based on certain events or periodically-assessed demand levels in order to optimize overall system efficiency.

At a macro level, liquid cooling arrangement 200 incorporates the liquid cooling subsystem 170 comprising the dry cooling unit 172 and pump unit 175, along with a feedback control system 210, a series of branches containing server racks 150-15L, and a liquid distribution circuit 105 to forward the cooling water to, and return heated water from, the server racks 150-15L. The liquid cooling subsystem 170 operates to have dry cooling unit 172 supply cooling water to the pump unit 175 to force the flow of cooling water to the server racks 150-15L, via liquid distribution circuit 105, as well as return the water heated by the server racks 150-15L, via liquid distribution circuit 105, back to the dry cooling unit 172 for recooling of the heated water and recirculation.

The pump unit 175 is configured with a constant pressure operation setting mode that enables the pump to function under a set constant pressure level. The pump unit 175 may comprise a variable frequency driver (VFD) that, based on set parameters and detected demands, dynamically adjusts the the rotational frequency/speed (in rpms) of a pump impeller (not shown) that directly bears on the pump pressure (in kPa) and related volumetric cooling liquid flow rate capacity (in L/s). Accordingly, pump unit 175 is fluidly-coupled to the liquid distribution circuit 105 and configured to operate at a pump speed that forcibly urges the flow of the cooling liquid throughout the liquid distribution circuit 105 at adequate flow rates.

As shown in FIG. 2, input pressure sensor 204 measures the pressure (Pi) of the cooling liquid flow received by the pump unit 175 and output pressure sensor 212 measures the pressure (Po) of the cooling liquid flow forcibly outputted by pump unit 175. The input and output pressure sensors 204, 212 may be directly disposed on respective input and output ends of pump unit 175 or respectively immediately disposed upstream and downstream from pump unit 175.

As also shown, each of the server rack 150-15L branches respectively incorporate a “smart” valve 230-2L0 that may comprise an automatic balancing pressure control (ABQM) valve that is pressure-independent and temperature-responsive. ABQMs are configured to regulate their openings to maintain a consistent, stable cooling liquid flow, regardless of pressure fluctuations, in an autonomous manner. In some implementations ABQMs are also configured to communicate with a control unit that, based on control instructions, are capable of providing a further degree of overall system control.

Moreover, each of the server racks 150-15L branches also incorporates an input temperature sensor 232-2L2 for measuring the temperature of the cooling liquid Ti prior to the corresponding server racks 150-15L and an output temperature sensor 238-2L8 for measuring the temperature of the cooling liquid To after the corresponding server racks 150-15L. The server racks 150-15L then determine the temperature difference ΔT of the cooling liquid based on the Ti and To values.

Furthermore, control system 210 incorporates a feedback control loop comprising a control unit 500, a feedback logic module 206, and a comparator 208. In certain nonlimiting embodiments, the control unit 500 may be integrated with, or part of, the pump unit 175 configuration. The feedback control system 210 operation may be activated upon initial system installation/commissioning as well as at predetermined scheduled intervals (e.g., every 0.5 hr., 1 hr., 2 hrs, etc.) to provide periodically-updated pressure data based on observed and/or historical demand level variations throughout the day, week, holidays, season, etc.

The control unit 500 of feedback control system 210 is shown to be communicatively-coupled to the pump unit 175, the input and output pressure sensors 204, 212. In some embodiments, the control unit 500 is also communicatively-coupled to the smart valves 230-2L0. In some embodiments, the control unit 500 is also communicatively-coupled to input/output temperature sensors 232-2L2, 238-2L8 of server rack 150-15L branches. As will be described in greater detail below, the communicative arrangement between components of the server rack 150-15L branches, allows feedback control loop of system 210 to dynamically control the pump unit 175 based on certain detected periodically-updated sensor levels, such as, for example, pressure differences ΔP, temperature differences ΔT, and a predetermined desired temperature difference ΔTd of X° K representing a desired temperature difference value between overall input and output temperatures to achieve an optimal cooling liquid flow rate mₒₚₜ.

It should be appreciated that the comprehensive architecture of liquid cooling arrangement 200 depicted by FIG. 2 allows for various operational applications to dynamically adjust the cooling liquid pressure to efficient levels. In one such operational application, the control unit 500 may only communicate with pump unit 175 and not have control communications to/from the components or sensors of the server rack 150-15L branches.

For this operational application, the control unit 500 directs the pump unit 175 to operate fully at 100% speed to generate maximum pressure of cooling liquid flow. In some embodiments, the control unit 500 directs the smart valves 230-2L0 to fully open at 100% capacity or at a 100% of the needed server rack flow.

The control unit 500 then determines an optimal volume flow rate (mₒₚₜ) based on the heat load level Q of the server rack 150-15L and an empirical operational characteristic based on pump speeds and corresponding volume flow rates. In particular, the optimal flow rate mₒₚₜ determination is conducted feedback logic module 206 which utilizes empirically-observed functional relationships between pump unit pressure (in kPa), cooling liquid volumetric flow rate (in L/s), pump power (in kW), and pump speed (in rpms) to identify the efficient pump operations given the measured prevailing conditions and/or desired threshold values.

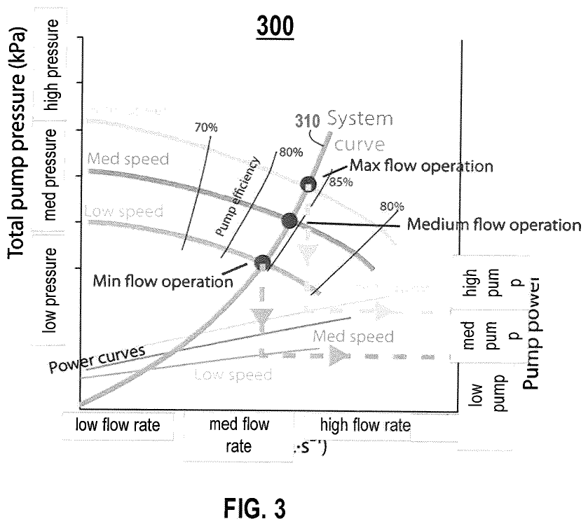

The empirical functional relationships between pump unit pressure, cooling liquid flow rate, pump power, and pump speed is represented by the exemplary pump characteristics graph 300 of FIG. 3, in accordance with the non-limiting embodiments of the present disclosure. As shown, graph 300 defines a system curve 310 that provides possible efficient volumetric flow rates mₒₚₜₛ based on intersecting operating points with high, medium, and low pump speed characteristic curves. The intersecting points further indicate the corresponding high, medium, and low pump power consumption levels required to achieve the optimal flow rates mₒₚₜₛ. It will be appreciated that, while most pump units generally exhibit the characteristic curves of graph 300, pump specifications and operating parameter values may vary from model to model. For this reason, graph 300 does not include specific values and relies instead on providing ranges indicated by high, medium, and low levels.

The empirical pump-related relationships of graph 300 enable the feedback logic 206 of control system 210 to determine the optimal flow rate mₒₚₜ from the possible flow rates mₒₚₜₛ based on certain factors, such as, for example, heat load level Q, cooling liquid temperature difference ΔT, pressure difference ΔP, desired temperature difference ΔTd of X° K, etc. For instance, feedback logic 206 may determine the optimal flow rate mₒₚₜ based on the updated temperature difference value ΔT and a desired temperature difference ΔTd (e.g., 15° K, 20° K, 25° K, etc.). By way of background, the well known thermodynamic equation for determining a heat load Q is:

$$Q = m \cdot Cp \cdot Δ T , where :$$

$$m : r epresents the volumetric flow rate ;$$

$$Cp : represents the specific heat ; and$$

$$Δ T : represents the temperature difference .$$

Therefore, based on the known heat load Q, the specific heat Cp of the cooling liquid, and the desired temperature difference ΔTd, the optimal cooling liquid flow rate mₒₚₜ can be determined by manipulating the equation to read as follows:

$${m}_{opt} = Q / ( Cp \cdot Δ T )$$

Based on the manipulated equation, feedback logic module 206 is able to determine the pump speed necessary to identify the efficient cooling liquid flow rate mₒₚₜ from the possible flow rates mₒₚₜₛ of system curve 310, in order to achieve the desired temperature difference ΔTd.

In turn, the control unit 500 directs pump unit 175 to reduce the pump speed to the lowest efficient level PS_{L} that maintains the optimal cooling liquid flow rate mₒₚₜ in order to optimize the efficiency of the power consumed by pump unit 175. Accordingly, the constant pressure operation setting mode of pump unit 175 is set to operate at the determined lowest efficient pump speed PS_{L}. It will be appreciated that the determination of the optimal volume flow rate mₒₚₜ and the lowest efficient pump speed PS_{L} may be performed over one or more iterations.

In another operational application, the control unit 500 is configured to have control communications with each of the components or sensors of the server rack 150-15L branches. That is, control unit 500 receives the updated input and output temperature levels Ti, To for each of the server rack 150-15L branches to quantify the temperature difference ΔT by calculating the difference, via comparator 208, between the updated input temperature levels Ti and the updated output temperature levels To. It will be appreciated that during the comparator stage, the smart valves 230-2L0 remain in a “frozen” state.

In turn, the control unit 500 directs pump unit 175 to fully operate at 100% capacity. The control unit 500 then receives the updated pump unit input and output pressure levels Pi, Po to

quantify the pressure difference ΔP by calculating the difference between the updated input pump pressure level Pi and the updated output pump pressure level Po. In some embodiments, the control unit 500 directs the smart valves 230-2L0, via control instructions, to fully open at 100% to minimize the pressure drop level of arrangement 200.

Armed with the quantified updated pressure and temperature differences ΔP, ΔT, the feedback logic 206 of control system 210 determines the optimal flow rate mₒₚₜ based on the updated pressure difference ΔP to have the temperature difference ΔT achieve and maintain the predetermined desired temperature difference ΔTd of X° K representing a desired temperature difference value between overall input and output temperatures. The control unit 500 then directs pump unit 175 to reduce the pump speed to the lowest efficient level PS_{L} that maintains the optimal cooling liquid flow rate mₒₚₜ in order to optimize the efficiency of the power consumed by pump unit 175. Accordingly, the constant pressure operation setting mode of pump unit 175 is set to operate at the determined lowest efficient pump speed PS_{L}.

As noted above, the feedback control system 210 operation may be activated upon certain events, such as, initial system installation/commissioning, predetermined scheduled intervals (e.g., every 0.5 hr., 1 hr., 2 hrs, etc.) to provide periodically-updated pressure data based on observed and/or historical demand level variations throughout the day, week, holidays, season, etc. Moreover, the feedback control system 210 operation, the determination of the optimal volume flow rate mₒₚₜ and/or the pump constant pressure operational mode setting may be initiated to increase/decrease in the event of detected substantial cooling liquid flow rate changes or increased due to detected increased temperatures of server racks 150-15L resulting from increased processor demand levels.

In this manner, the configuration of liquid cooling arrangement 200 provides for the intelligent control of pump operations to dynamically adjust the cooling liquid flow rate in response to fluctuating demand levels in order to optimize pump efficiency and power consumption.

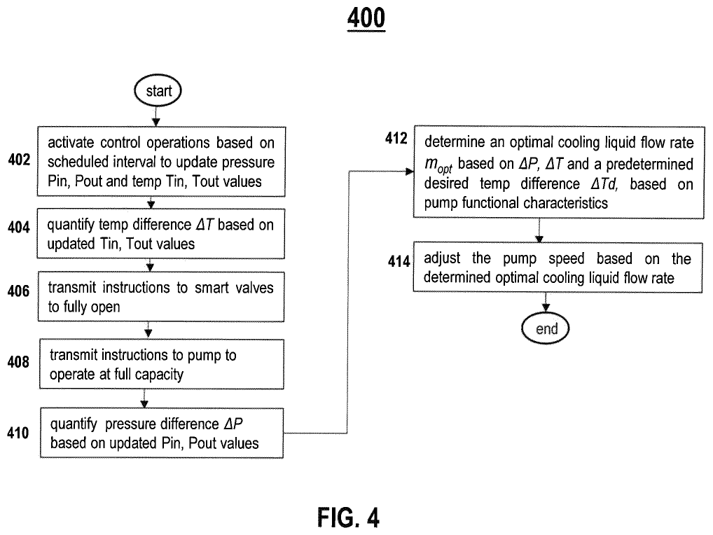

FIG. 4 depicts a flow diagram of process 400 for periodically adjusting the control of the pump unit operations of the liquid cooling arrangement based on detected demand levels, in accordance with the nonlimiting embodiments of the present technology.

Process 400 commences at task block 402, in which control operations are activated to update input and output pressure levels Pi, Po and input and output temperature levels Ti, To. As noted above, control operations may be activated at predetermined scheduled intervals (e.g., every 0.5 hr., 1 hr., 2 hrs., etc.).

At task block 404, control unit 500 quantifies the temperature difference ΔT by calculating the difference between the updated input temperature levels Ti and the updated output temperature levels To.

At task block 406, control unit 500 may optionally direct the smart valves 230-2L0 to fully open at 100% to minimize the pressure drop level of arrangement 200. At task block 408, control unit 500 may direct pump unit 175 to fully operate at 100% capacity.

At task block 410, control unit 500 quantifies the pressure difference ΔP by calculating the difference between the updated input pressure level Pi and the updated output temperature level Po.

At task block 412, control system 210 determines an optimal cooling liquid flow rate mₒₚₜ based on ΔP, ΔT and a predetermined desired temp difference ΔTd, based on the pump-related functional characteristics provided by graph 300. That is, as noted above, the feedback logic 206 of control system 210 utilizes the functional characteristic relationships between the pump unit pressure, cooling liquid flow rate, pump power, and pump speed of graph 300 to: (a) determine possible optimal volumetric flow rates mₒₚₜ along the system curve 310 of graph 300; and (b) utilize the thermodynamic heat load Q equation to identify the optimal flow rate mₒₚₜ that achieves the desired temperature difference ΔTd of X° K.

Finally, at task block 406, control unit 500 directs the pump unit 175 to adjust (either increase or decrease) the pump speed to attain the optimal cooling liquid flow rate mₒₚₜ, which also directly bears on the power consumed by pump unit 175.

In this manner, process 400 provides a method for the intelligent control of pump operations to dynamically adjust the cooling liquid flow rate in response to fluctuating demand levels in order to optimize pump efficiency and power consumption.

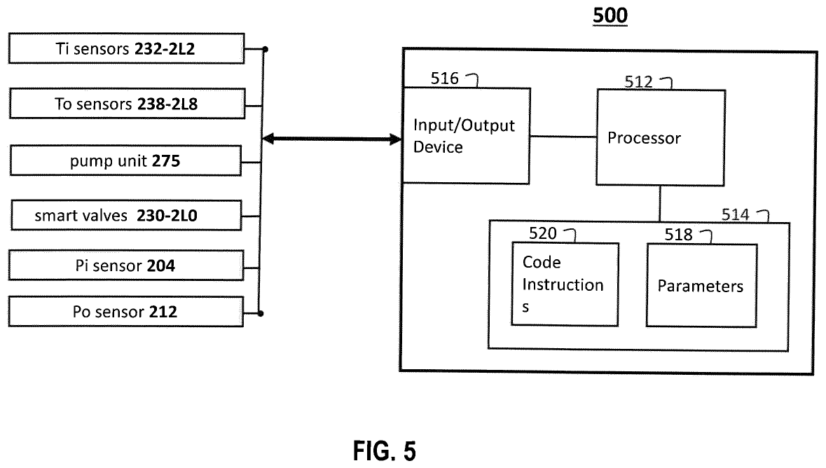

FIG. 5 illustrates a functional block diagram of controller 500 configured to execute the control processing operations noted above, in accordance with embodiments of the present technology.

As shown, controller 500 comprises a processor or a plurality of cooperating processors (represented as processor 512 for simplicity), a memory device or a plurality of memory devices (represented as memory device 514 for simplicity), one or more input devices and output devices, the input and output devices being possibly combined into one or more input/output devices (represented as a single input/output device 516 for simplicity). The processor 512 is operatively connected to the memory device 514 and to the input/output device 516. The memory device is configured to store a list 518 of relevant parameters. The memory device 514 may comprise a non-transitory computer-readable media for storing control logic instructions 520 that are executable by the processor 512 and, in particular, the executing process 300 for optimally controlling the application of cooling water to the evaporating pad 150.

As shown, processor 512 is communicatively coupled, via the input/output interface 516, to the one or more of the input temperature Ti sensors 232-2L2, the output temperature To sensors 238-2L8, the pump unit 275, the smart (i.e., ABQM) valves 230-2L0, the input temperature Pi sensor 204, and the output temperature Po sensor 204. The processor 512 is configured to execute the control logic instructions 520 stored in the memory device 514 to implement the various above-described functions of the controller 500.

While the above-described implementations have been described and shown with reference to particular steps performed in a particular order, it will be understood that these steps may be combined, sub-divided, or re-ordered without departing from the teachings of the present technology. At least some of the steps may be executed in parallel or in series. Accordingly, the order and grouping of the steps is not a limitation of the present technology.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. A liquid cooling arrangement for providing a cooling liquid to datacenter rack-mounted server data processing assemblies, comprising:
a server branch comprising a server rack for housing the rack-mounted server processing assemblies and a smart control valve configured to control a flow of the cooling liquid supplied to the server rack;
a liquid cooling subsystem comprising a pump unit configured to forcibly urge a flow of the cooling liquid from the liquid cooling subsystem (170) to and from the server rack and an output pressure sensor configured to measure the pressure of the cooling liquid flow (Po) forcibly urged by the pump unit, the pump unit configured with a constant pressure operational mode setting that controls a speed of the pump unit to provide a cooling liquid pressure at a set constant pressure level;
a liquid distribution circuit fluidly-coupled to the liquid cooling subsystem, the smart control valve, and the server rack, the liquid distribution circuit configured to convey the cooling liquid from the liquid cooling subsystem to the server rack and convey the heated liquid from the server rack back to the liquid cooling subsystem for recooling and recirculation therethrough;
a feedback control system comprising a control unit and receiving a heat load level Q of the server rack for determining the constant pressure operational mode setting of the pump unit, the control unit configured with executable instructions to:
direct the pump unit to operate at full speed to provide a maximum pressure of cooling liquid flow;
determine an optimal volume flow rate (mₒₚₜ) based on the heat load level Q of the server rack and an empirical operational characteristic based on pump speeds and corresponding volume flow rates;
determine a lowest efficient pump speed (PS_{L}) that maintains the optimal cooling liquid flow rate mₒₚₜ; and
set the constant pressure operational mode setting of the pump unit to operate in accordance with the determined lowest efficient pump speed PS_{L}.

2. The liquid cooling arrangement of claim 1, wherein the control unit is further configured to receive a cooling liquid temperature difference ΔT between input and output server rack cooling liquid temperatures,
wherein the optimal volume flow rate (mₒₚₜ) is further based on a desired predetermined temperature difference ΔTd of X° K of the cooling liquid.

3. The liquid cooling arrangement of claim 1, wherein the empirical pump operational characteristics define an efficient system operations curve relative to volume flow rates, pump speeds, and pump power consumption levels.

4. The liquid cooling arrangement of claim 1, wherein the determination of the optimal volume flow rate mₒₚₜ and the lowest efficient pump speed PS_{L} is performed over one or more iterations.

5. The liquid cooling arrangement of claim 1, wherein the output pressure sensor is disposed on an outlet side of the pump unit.

6. The liquid cooling arrangement of claim 1, wherein the control unit is further configured to communicate with, and receive from, input and output cooling liquid temperatures levels Ti, To of the server rack to quantify the cooling liquid temperature difference ΔT and pump unit input and output pressure levels Pi, Po to quantify a pump pressure difference ΔP.

7. The liquid cooling arrangement of claim 6, wherein the determination of the optimal volume flow rate mₒₚₜ and/or the constant pressure operational mode setting of the pump unit (175) includes applying the pump pressure difference ΔP to the empirical operational characteristic.

8. The liquid cooling arrangement of claim 1, wherein the control unit is integrated with, or part of, the pump unit configuration.

9. The liquid cooling arrangement of claim 1, wherein the determination of the optimal volume flow rate mₒₚₜ and the setting of the pump unit constant pressure operational mode is initiated at periodic intervals.

10. The liquid cooling arrangement of claim 1, wherein the setting of the pump unit constant pressure operational mode is initiated based on detected cooling liquid flow rate changes.

11. The liquid cooling arrangement of claim 1, wherein the setting of the pump unit constant pressure operational mode is initiated based on detected increased server rack temperatures due resulting from processing demands.

12. The liquid cooling arrangement of claim 1, wherein the control unit is further configured with executable instructions to direct the smart control valve to open at maximum flow rate capacity prior to determining the optimal volume flow rate (mₒₚₜ).

13. A liquid cooling method for providing a cooling liquid to datacenter server data processing assemblies of a server rack, comprising:
communicating with an input server rack temperature sensor, output server rack temperature sensor, input pump unit pressure sensor, output pump unit pressure sensor, and a smart control valve;
directing the pump unit to operate at full capacity;
quantifying a pressure difference (ΔP) between the input pressure sensor measurement and the output pressure sensor measurement;
determining an optimal volume flow rate (mₒₚₜ) based on a desired predetermined temperature difference ΔTd of X° K representing a desired temperature difference value between overall input and output temperatures and empirical pump operational characteristics regarding pump speeds and corresponding volume flow rates;
determining a lowest efficient pump speed (PS_{L}) that maintains the optimal cooling liquid flow rate mₒₚₜ; and
setting the constant pressure operational mode setting of the pump unit to operate in accordance with the determined lowest efficient pump speed PS_{L}.

14. The liquid cooling method of claim 13, wherein the empirical pump operational characteristics define an efficient system operations curve relative to volume flow rates, pump speeds, and pump power consumption levels.

15. The liquid cooling method of claim 14, wherein the determining of the optimal volume flow rate mₒₚₜ and the lowest efficient pump speed PS_{L} is performed over one or more iterations.

16. The liquid cooling method of claim 14, wherein an output pressure sensor disposed on an outlet side of the pump unit is configured to determine the output pressure sensor measurement.

17. The liquid cooling method of claim 14, wherein the determination of the optimal volume flow rate mₒₚₜ and the setting of the pump unit constant pressure operational mode is initiated at periodic intervals.

18. The liquid cooling method of claim 14, wherein the setting of the pump unit constant pressure operational mode is initiated based on detected cooling liquid flow rate changes.

19. The liquid cooling method of claim 14, wherein the setting of the pump unit constant pressure operational mode is initiated based on detected increased server rack temperatures due resulting from processing demands.

20. A non-transitory computer-readable medium comprising executable instructions which, when executed by at least one processor, cause the at least one processor carry out steps of a liquid cooling method for providing a cooling liquid to datacenter server data processing assemblies of a server rack, the method comprising:
communicating with an input server rack temperature sensor, output server rack temperature sensor, input pump unit pressure sensor, output pump unit pressure sensor, and a smart control valve;
directing the pump unit to operate at full capacity;
quantifying a pressure difference (ΔP) between the input pressure sensor measurement and the output pressure sensor measurement;
determining an optimal volume flow rate (mₒₚₜ) based on a desired predetermined temperature difference ΔTd of X° K representing a desired temperature difference value between overall input and output temperatures and empirical pump operational characteristics regarding pump speeds and corresponding volume flow rates;
determining a lowest efficient pump speed (PS_{L}) that maintains the optimal cooling liquid flow rate mₒₚₜ; and
setting the constant pressure operational mode setting of the pump unit to operate in accordance with the determined lowest efficient pump speed PS_{L}.
